(19) United States
(12) Patent Application Publication
(10) Pub. No.: US 2022/0363830 A1
(43) Pub. Date: Nov. 17, 2022

(54) POLYIMIDE COMPOSITE, PREPARATION METHOD AND APPLICATION THEREOF

(71) Applicant: Wuhan China Star Optoelectronics Semiconductor Display Technology Co., Ltd., Wuhan (CN)

(72) Inventor: Yamin WANG, Wuhan (CN)

(21) Appl. No.: 16/616,452

(22) PCT Filed: Sep. 23, 2019
(86) PCT No.: PCT/CN2019/107231

§ 371 Date: Nov. 23, 2019

(30) Foreign Application Priority Data
May 30, 2019 (CN) 201910460915.3

(51) Int. Cl. C08G 73/10; H01L 51/00

(52) U.S. Cl. CPC C08G 73/1071; C08G 73/1039; C08G 73/1032; H01L 51/0097; H01L 2251/5338

(57) ABSTRACT

The present invention provides a polyimide composite having material properties suitable for preparing a polyimide film having high transmittance, high stability, and a good mechanical property, so that it can be used as a substrate material of an organic light-emitting diode (OLED), an encapsulating film material, and so on, but are not limited thereto. The polyimide composite has a molecular structural formula as follow:

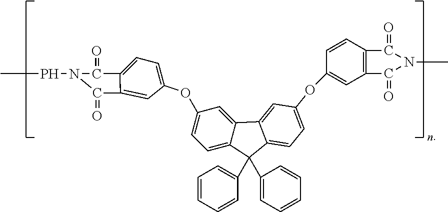

### BACKGROUND OF INVENTION

### Field of Invention

The present invention relates to a field of functional materials, and in particular, to a functional polyimide (PI) material which can be used for preparation of a substrate layer or an encapsulating film or the like of a display panel, but is not limited thereto.

### Description of Prior Art

It is known that a conventional polyimide material often has a denser rigid structure and a strong intermolecular interaction, which ultimately leads to poor processing properties and deep memory color, correspondingly limiting its application scope. For a description of its characteristics, please refer to the relevant content in the following paper: Claudio A. T., Luis. H. T. ect, Synthesis and characterization of aromatic poly(ether-imide)s based on bis(4-(3,4-dicarboxyphenoxy)phenyl)—R,R silane anhydrides (R═Me, Ph)—spontaneous formation of surface micropores from THF solutions[J]. RSC Advances. 2016, 6: 49335-49347. In this regard, the industry has made some corresponding improvements to expand the applications of polyimide.

At present, conventional methods for improving the processing performance of polyimides mainly focus on the modification of polyimide structures, generally novel diamine and dianhydride structures. For example, an introduction of long aliphatic chains (specific technical solutions can be referred to the relevant content in the following paper: Zhou, Y., Chen, G. F., ect. Synthesis and characterization of transparent polyimides derived from ester-containing dianhydrides with different electron affinities[J]. RSC Advances. 2015, 5: 79207-79215.), and an introduction of bulk fluorine side groups are employed to solve some of the above disadvantages (specific technical solutions can be referred to the relevant content in the following paper: Chung, C. L. and Hsiao, S. H. Novel organosoluble fluorinated polyimides derived from 1,6-bis(4-amino-2-trifluoromethylphenoxy) naphthalene and aromatic dianhydrides[J]. Polymer, 2008, 49: 2476-2485.).

However, in most cases, as its light transmittance increases, its thermal and mechanical properties are always degraded. Therefore, it is indeed necessary to develop a novel polyimide composite to overcome the drawbacks of the prior art.

### SUMMARY OF INVENTION

An object of the present invention is to provide a polyimide composite having material properties suitable for preparing a polyimide film having high transmittance, high stability, and a good mechanical property, so that it can be used as a substrate material of an organic light-emitting diode (OLED), an encapsulating film material, and so on, but are not limited thereto.

Technical solutions adopted by the present invention is as follows:

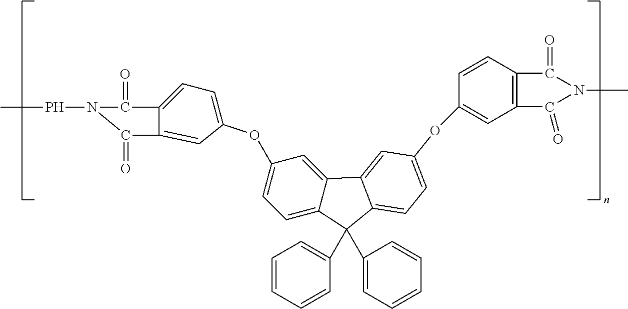

A polyimide composite having a molecular structural formula as follow:

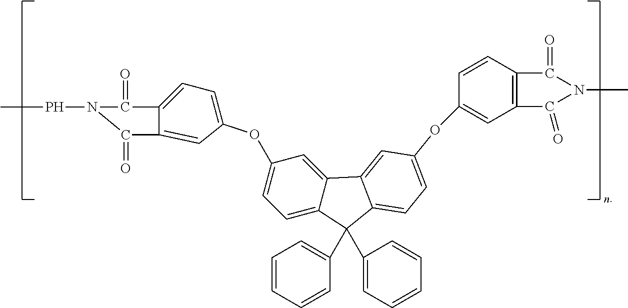

Further, in various embodiments of the present invention, a polyamic acid (PAA) precursor of the polyimide composite has a molecular structural formula as follow:

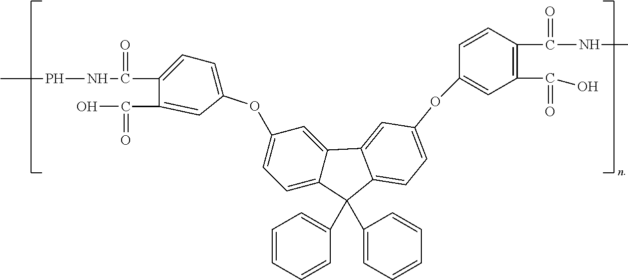

Further, in various embodiments of the present invention, raw materials for preparing the polyamic acid precursor comprise a diamine (NH₂—PH—NH₂) and a fluorene-containing aromatic dianhydride.

Further, in various embodiments of the present invention, the fluorene-containing aromatic dianhydride has a molecular structural formula as follow:

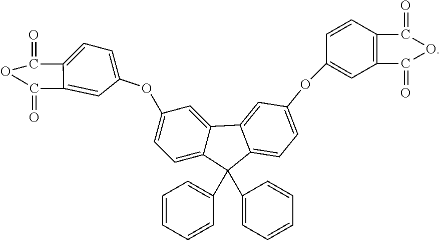 [SMILES: O=C1OC(=O)c2cc(Oc3ccc4c(c3)-c3cc(Oc5ccc6c(c5)C(=O)OC6=O)ccc3C4(c3ccccc3)c3ccccc3)ccc21]

Further, in various embodiments of the present invention, the PH in the diamine (NH₂—PH—NH₂) has a molecular structural formula selected from one of the following molecular structural formulas a, b and c:

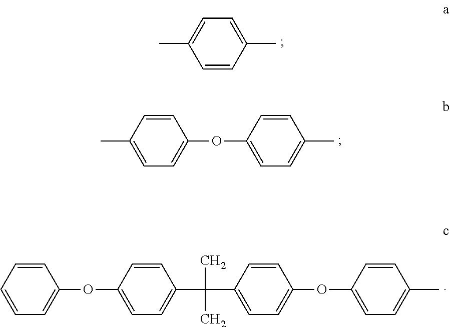

Further, in various embodiments of the present invention, a raw material for preparing the fluorene-containing aromatic dianhydride comprises a fluorene-containing aromatic dicarboxylic acid, which has a molecular structural formula as follow:

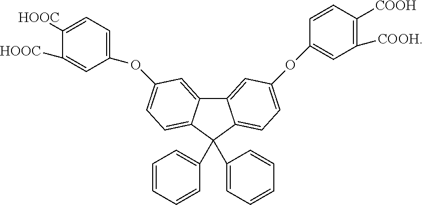 [SMILES: O=C(O)c1ccc(Oc2ccc3c(c2)-c2cc(Oc4ccc(C(=O)O)c(C(=O)O)c4)ccc2C3(c2ccccc2)c2ccccc2)cc1C(=O)O]

Further, in various embodiments of the present invention, raw materials for preparing the fluorene-containing aromatic dicarboxylic acid comprise fluorene-containing aromatic diol, 4-bromophthalic acid, and toluene.

Further, in various embodiments of the present invention, the fluorene-containing aromatic diol has a molecular structural formula selected from one of the following molecular structural formulas a, b and c:

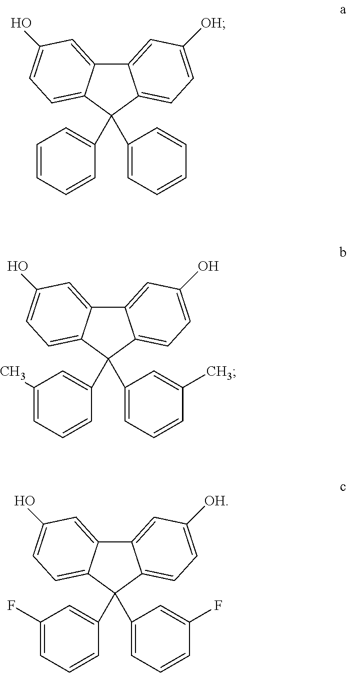 [SMILES: Oc1ccc2c(c1)-c1cc(O)ccc1C2(c1ccccc1)c1ccccc1 ; Cc1cccc(C2(c3cccc(C)c3)c3ccc(O)cc3-c3cc(O)ccc32)c1 ; Oc1ccc2c(c1)-c1cc(O)ccc1C2(c1cccc(F)c1)c1cccc(F)c1]

Further, another aspect of the present invention provides a method of preparing the polyimide composite, comprising the following steps:
Step S1, adding fluorene aromatic diol, 4-bromophthalic acid, toluene, and a solvent to a reaction vessel, stirring at room temperature for 1 to 4 hours, and then heating to 70-90° C. and maintaining the temperature for 10-20 hours, to obtain a mixed solution of fluorene-containing aromatic dicarboxylic acid;
Step S2, adding a mixed solvent of water and ethanol to the mixed solution, stirring the mixed solution at a temperature of 70-90° C. for 48-96 hours for carrying out a reaction, and filtering and washing the mixed solution after the reaction to obtain a fluorene-containing aromatic dianhydride product;
Step S3, adding the fluorene-containing aromatic dianhydride, a diamine, and a solvent to a reaction vessel, and stirring at room temperature for 24 to 96 hours, to obtain a polyamic acid precursor as a reaction product; and
Step S4, adding toluene to the polyamic acid precursor, heating to 150-250° C. for 4-6 hours, then cooling to 70-90° C., filtering the mixed solution after the reaction, removing 60% to 80% of the solvent from the filtered solution, and then carrying out a crosslinking reaction at a constant temperature of 400 to 500° C., thereby obtaining the polyimide composite of the present invention.

Further, in various embodiments of the present invention, wherein in the step S1, the cerium aromatic diol and the 4-bromophthalic acid have a molar ratio of (1.9 to 2.5):1.

Further, in various embodiments of the present invention, wherein in the step S1, the solvent comprises N,N-dimethylformamide (DMF).

Further, in various embodiments of the present invention, wherein in the step S1, a basic substance is further added to keep the mixed solution weakly alkaline, for example, anhydrous potassium carbonate, but is not limited thereto.

Further, in various embodiments of the present invention, wherein in the step S2, the water and ethanol have a volume ratio ranging from 90:10 to 95:5.

Further, in various embodiments of the present invention, wherein in the step S3, a reaction is carried out under a protection of argon.

Further, in various embodiments of the present invention, wherein in the step S3, the solvent comprises N-methylpyrrolidone (NMP solvent).

Further, in various embodiments of the present invention, in the step S3, the mixed solution after the reaction is washed by using a hydrochloric acid solution having a mass fraction of less than 20% (or a hydrochloric acid solution having a concentration of 3 mol/L or less).

Further, in various embodiments of the present invention, wherein in the step S4, the crosslinking reaction is carried out under a protection of argon.

Further, in various embodiments of the present invention, wherein in the step S4, the solvent is removed by maintaining the filtrate in a vacuum environment at a temperature of 70-90° C. for 0.5 to 1 h.

Further, another aspect of the present invention provides an application of the polyimide composite according to the present invention, by using the polyimide composite to constitute a polyimide film provided on a glass substrate of a display panel.

Further, a further aspect of the present invention provides a method of preparing a polyimide film on the display panel according to the present invention, comprising the following steps:
providing a polyamic acid precursor solution of the polyimide composite according to the present invention, and coating the polyamic acid precursor solution on a glass substrate of a display panel;
removing 60 to 80% of the solvent in the polyamic acid precursor solution coated on the glass substrate at 70 to 90° C., and then carrying out a constant temperature prosess at a constant temperature of 400 to 500° C., to obtain the polyimide film formed on the glass substrate.

Further, in various embodiments of the present invention, the whole constant temperature process is carried out for 1.5 to 5 hours, wherein the constant temperature is kept for 20 to 80 minutes.

A baking stage in the constant temperature process can be divided into hard baking and soft baking. The hard baking is directly heating to the highest temperature, keeping the temperature unchanged for about 60 min, and then cooling down. The soft baking is a constant temperature platform with 2 or more times, and finally cooling down. Each constant temperature platform has a constant temperature time selected from about 20-60 min according to different conditions, such that, cross-linking and solvent removal of the polyamic acid material precursor solution at different constant temperature stages can be realized.

Further, in various embodiments of the present invention, the temperature is raised at a rate of 4 to 10° C./min in the temperature rising stage of the constant temperature process.

The present invention relates to a polyimide composite which introduces a novel fluorene-containing aromatic diol basic unit, thereby introducing a non-coplanar structure to prepare a dianhydride, wherein the non-coplanar structure in the polymer bends perpendicular to the main chain, thereby effectively loosing the tightly stacked polymer chains and reducing a chain interaction.

Further, the fluorene-containing structure is also introduced into the molecular structure of the composite according to the present invention. Since the fluorene-containing polycyclic ring has a refractive index higher than the benzene ring, the introduction of the fluorene group is advantageous for increasing light transmittance of the composite of the present invention. Moreover, the presence of a fluorene unit in the composite can also increase a content of the aromatic unit therein, thereby further improving the thermal stability of the polymer. The current substrate material of an organic light-emitting diode (OLED) still has some disadvantages, and the proposal of the composite material of the present invention provides a new idea to enrich the field of the substrate materials of the OLED.

However, it should be clarified that the polyimide composite according to the present invention is usable as a substrate material for an OLED display panel, and can achieve the above-mentioned advantageous effects, but it is only an application of the polyimide composite according to the present invention, and the polyimide composite according to the present invention is not limited to be used as the substrate material of the OLED display panel, and it can also have a wider applications, for example, as the encapsulating film materials, etc., as long as the performance parameters comply with the application requirements.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic view showing a process of a constant temperature process according to an embodiment of the present invention.

FIG. 2 is a schematic view showing a process of a constant temperature process according to another embodiment of the present invention.

FIG. 3 is a schematic view showing a process of a constant temperature process according to further another embodiment of the present invention.

FIG. 4 is a schematic view showing a process of a constant temperature process according to still another embodiment of the present invention.

FIG. 5 is a thermogravimetric analysis diagram of Film a composed of a polyimide composite according to another embodiment of the present invention.

FIG. 6 is a thermogravimetric analysis diagram of Film b composed of a polyimide composite according to further another embodiment of the present invention.

FIG. 7 is a thermogravimetric analysis diagram of Film c composed of a polyimide composite according to still another embodiment of the present invention.

FIG. 8 is a graph showing the transmittance performance of the film a shown in FIG. 5.

FIG. 9 is a graph showing the transmittance performance of the film b shown in FIG. 6.

FIG. 10 is a graph showing the transmittance performance of the film c shown in FIG. 7.

FIG. 11 is a graph showing thermomechanical performance of the film a of FIG. 5.

FIG. 12 is a graph showing thermomechanical performance of the film b illustrated in FIG. 6.

FIG. 13 is a graph showing thermomechanical performance of the film c of FIG. 7.

### DETAILED DESCRIPTION OF PREFERRED EMBODIMENTS

Hereinafter, a polyimide composite, a preparation method and a technical solution thereof according to the present invention will be further described in detail with reference to the accompanying drawings and embodiments.

The present invention relates to a structure of a polyimide composite and a preparation method thereof. In order to avoid unnecessary repetitive description and descript clearly, the polyimide composite structure according to the present invention will be described in detail below based on the preparation method.

The method of preparing the polyimide composite according to the present invention is performed by a four-step method, and can be summarized as follows according to different reaction intermediates:
Step S1, forming a fluorene-containing diacid intermediate: forming a fluorene-containing aromatic dicarboxylic acid;
Step S2; forming aromatic dianhydride;
Step S3, forming a polyamic acid precursor; and
Step S4, forming a polyimide composite.

The above four steps will be described in detail below with reference to specific parameters.

Step S1, forming a fluorene-containing aromatic dicarboxylic acid, wherein a fluorene aromatic diol (referred to as Compound A for convenience of description) (1 to 10.9 mmol), anhydrous potassium carbonate (10-20 mmol), 4-bromo O-phthalic acid (Compound B) (3-22 mmol), N,N-dimethylformamide (DMF) solvent (10-30 mL) and toluene (3-20 mL) solvent were added to a round bottom flask, and the mixture was stirred at room temperature for 1 to 4 hours, then heated to 80° C. for 10 to 20 hours to obtain a high-temperature mixed solution of fluorene-containing aromatic dicarboxylic acid (compound C) formed by the reaction.

Compound A is not the only possibility, and the molecular structure can be replaced by one of the following:

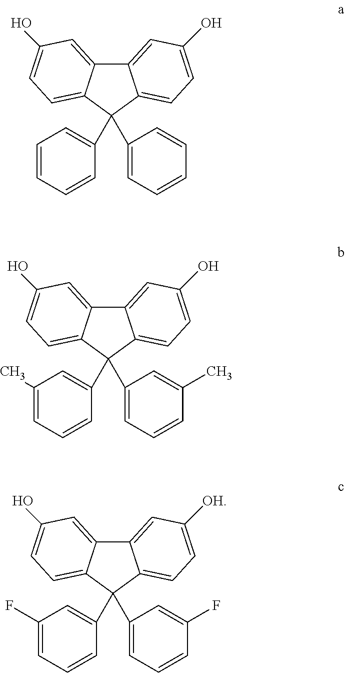

Compound C formed by the reaction has a molecular structural formula as follow:

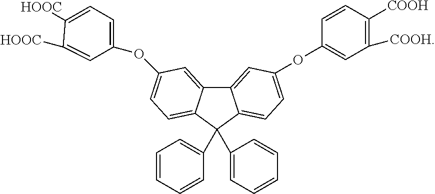 [SMILES: O=C(O)c1ccc(Oc2ccc3c(c2)-c2cc(Oc4ccc(C(=O)O)c(C(=O)O)c4)ccc2C3(c2ccccc2)c2ccccc2)cc1C(=O)O]

Step S2, forming an aromatic dianhydride, wherein a mixed solvent of water and ethanol (having a volume ratio of 90:10 to 95:5, with more than 25 mL of solvent for sufficient stirring for Compound C) was added to the high-temperature mixed solution, and the mixed solution was stirring at a temperature of 70-90° C. for 48-96 hours for carrying out a reaction.

The mixed solution after the reaction was filtered and washed with an appropriate amount of dilute hydrochloric acid (20-30 mL) to obtain a white solid, and then the white solid was filtered and washed with deionized water to finally obtain solid aromatic dianhydride (Compound D).

Compound D formed by the reaction has a structural formula as follow:

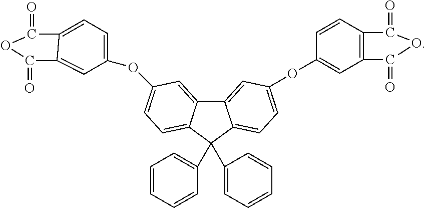 [SMILES: O=C1OC(=O)c2cc(Oc3ccc4c(c3)-c3cc(Oc5ccc6c(c5)C(=O)OC6=O)ccc3C4(c3ccccc3)c3ccccc3)ccc21]

Step S3, forming a polyamic acid precursor, wherein a diamine: NH2—PH—NH2 (Compound E) (1 mol) and N-methylpyrrolidone (NMP solvent) were added to an argon-protected round bottom flask, wherein the solvent was added in an amount right enough to sufficiently dissolve Compound E, and the reference amount was 20 to 150 mL, and then after Compound E was completely dissolved, Compound D (1 mol) of dianhydride monomer was added, followed by stirring for carrying out a reaction for 24 to 96 hours, to obtain the polyamic acid precursor (Polymer F).

The PH in the diamine (NH₂—PH—NH₂) has a molecular structural formula selected from one of the following molecular structural formulas a, b and c:

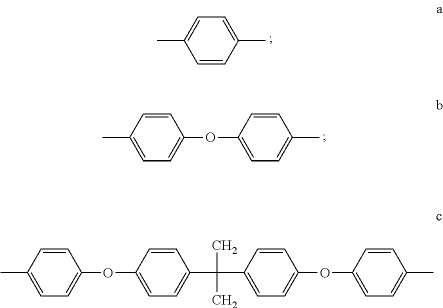

The polyamic acid precursor has a molecular structural formula as follow:

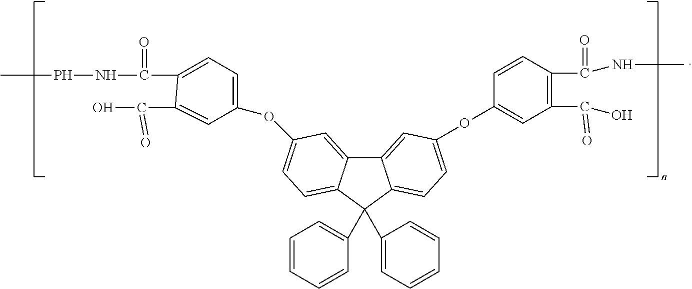

Step S4, forming a polyimide composite, wherein toluene (2-10 mL) was added to Polymer F, and heated to 150-250° C. in an argon atmosphere for carrying out a reaction for 4-6 h, then cooled to 80° C., followed by filtering the polyamic acid solution using an organic filter membrane, and then the obtained filtrate was spin-coated on a glass substrate, and then 70% of the solvent was removed by the filtrate in a vacuum environment at 80° C. for 0.5 to 1 h, and the dried filtrate was placed in an oven device to perform a constant temperature process (Recipe) for cross-linking and curing, thereby obtaining a polyimide film attached to the glass substrate, which is made of a material, the polyimide composite according to the present invention.

Then, the glass substrate and a film thereon can be immersed in deionized water for 72-96 hours, so that the polyimide film can be freely peeled off, and dried at 80° C., finally to obtain the polyimide film composed of the polyimide composite according to the present invention, which can be used for subsequent film property testing.

The polyimide composite has a molecular structural formula as follow:

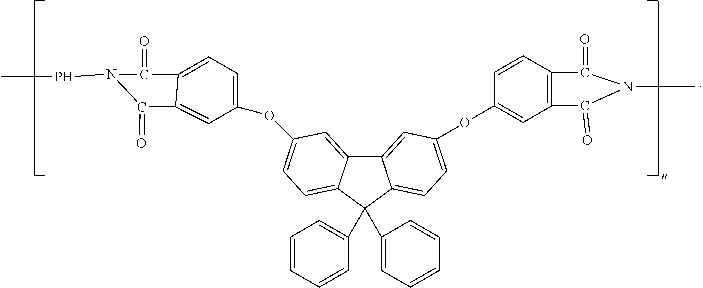

Further, still another embodiment of the present invention provides an application of the polyimide composite according to the present invention to a polyimide film of a display panel.

Further, further another aspect of the present invention provides a method of preparing a polyimide film composed of the polyimide composite on the display panel according to the present invention, comprising the following steps:
providing a polyamic acid precursor solution of the polyimide composite according to the present invention, and coating the polyamic acid precursor solution on a glass substrate of a display panel;
removing 60 to 80% of the solvent in the polyamic acid precursor solution coated on the glass substrate at 70 to 90° C., and then carrying out a constant temperature process at a constant temperature of 400 to 500° C., to obtain the polyimide film formed on the glass substrate.

Further, in various embodiments of the present invention, the whole constant temperature process is carried out for 1.5 to 5 hours, wherein the constant temperature is kept for 20 to 80 minutes.

For example, the baking stage in the constant temperature process can be divided into hard baking and soft baking. The hard baking is directly heating to the highest temperature, keeping the temperature unchanged for about 60 min, and then cooling down. The soft baking is a constant temperature platform with 2 or more times, and finally cooling down. Each constant temperature platform has a constant temperature time selected from about 20˜60 min according to different conditions, such that, cross-linking and solvent removal of the polyamic acid material precursor solution at different constant temperature stages can be realized. The temperature is raised at a rate of 4 to 10° C./min in the temperature rising process of the constant temperature process.

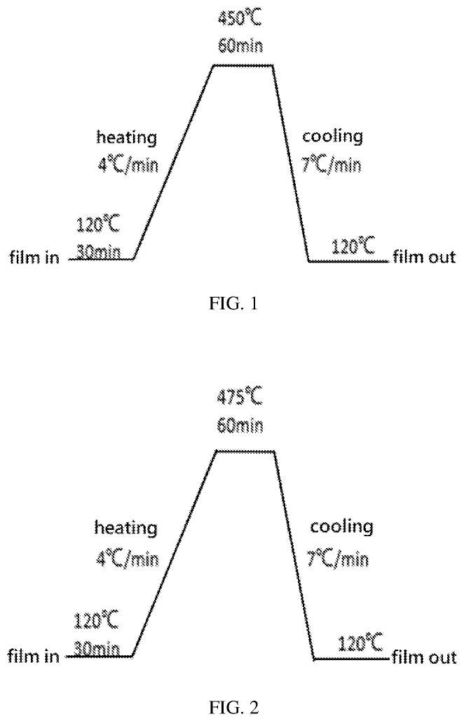

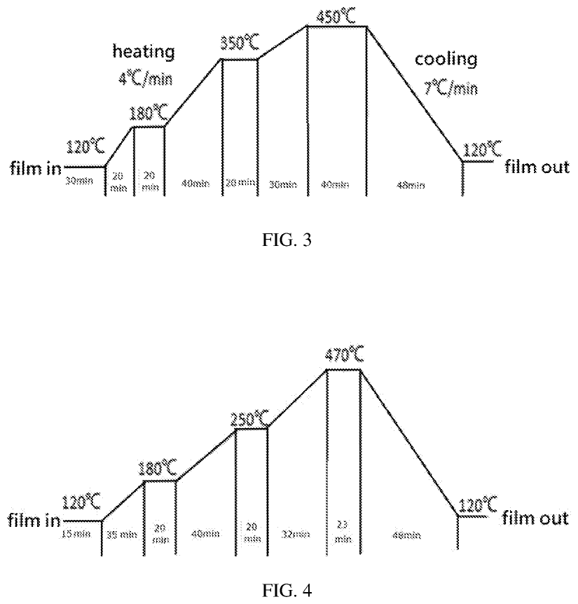

Specifically, please refer to FIG. 1 to FIG. 4, which respectively illustrate schematic views showing four constant temperature processes according to various embodiments of the present invention.

According to the above disclosure, the above three different diamine monomers (PH=a, b, or c) are used as materials of the corresponding polyimide films, respectively, referred as Film a, Film b and Film c.

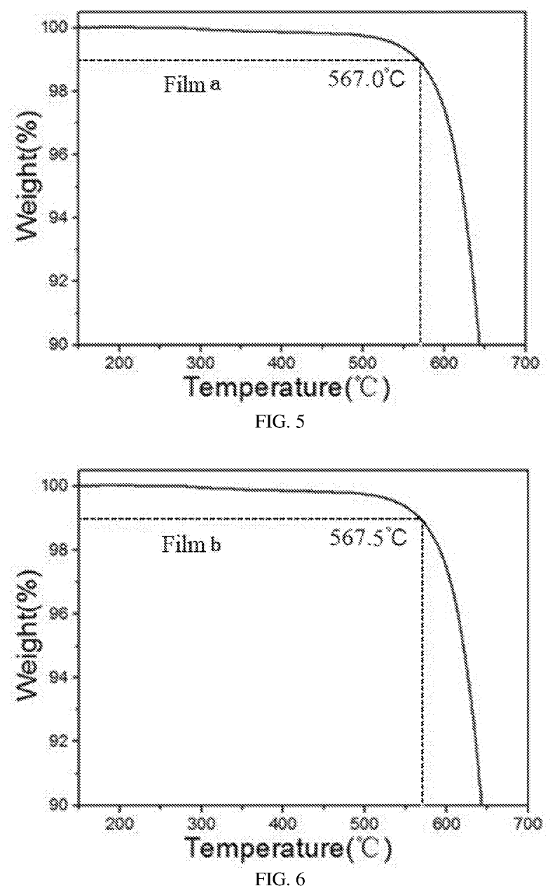

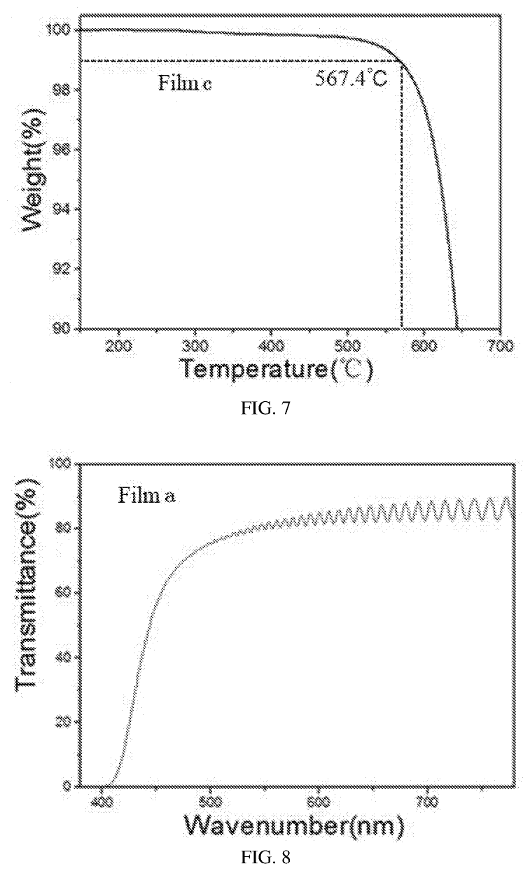

The above films were subjected to thermogravimetric analysis, and their specific performance analysis are shown in FIGS. 5-7, respectively. It can be seen from FIGS. 5-7 that the thermogravimetry of these films is basically the same, so it can be considered that the introduction of the di-fluorene group to the dianhydride plays a decisive role in the thermal thermogravimetric performance of the final polyimide film, while the diamine has little effect on the thermogravimetric performance, only about 1% of its thermogravimetric mass, and the temperature is about 570° C., which is very beneficial in the current generation of polyimide film, mainly due to a benzene ring structure formed by the fluorene group.

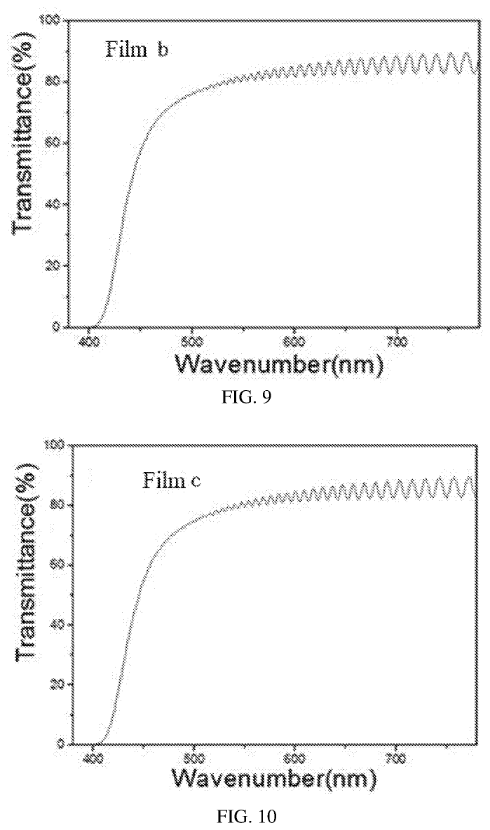

Further, please refer to FIGS. 8 to 10, which respectively illustrate the permeability properties of Film a, Film b, and Film c. As shown in the FIGS. 8 to 10, Film a, Film b, and Film c have good permeability.

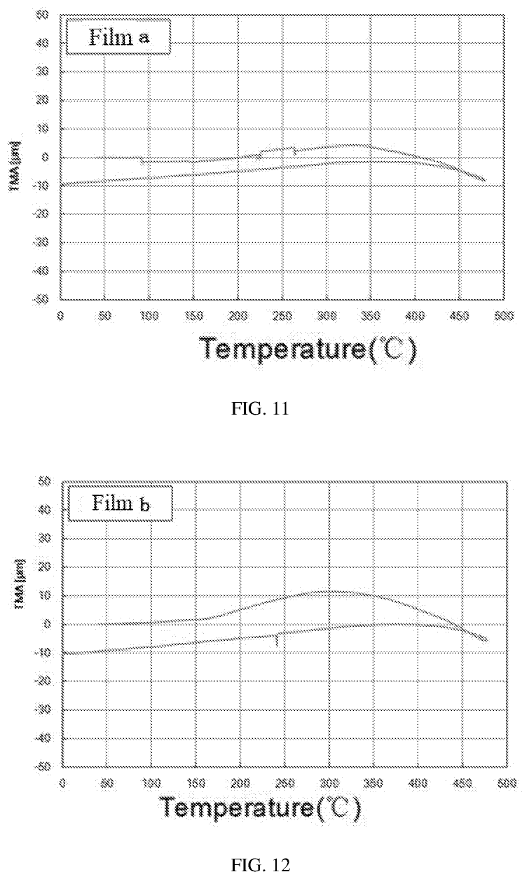

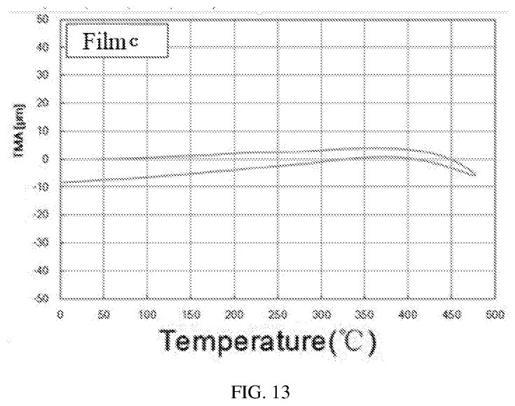

Further, Film a, Film b, and Film c were subjected to a tensile testing. It is found that a maximum elongation can reach 21%, and a maximum tensile force can reach 100 MPa. The thermal expansion coefficient is about 3.8 at a temperature ranging from 50 to 300° C. Please refer to FIGS. 11 to 13, which respectively illustrate the thermomechanical properties of Film a, Film b, and Film c, respectively. As shown in FIGS. 11 to 13, the thermomechanical properties exhibited by Film a, Film b, and Film c comply with standards of flexible substrates used in the display panels in the industry.

The present invention relates to a polyimide composite which introduces a novel fluorene-containing aromatic diol basic unit, thereby introducing a non-coplanar structure to prepare a dianhydride, wherein the non-coplanar structure in the polymer bends perpendicular to the main chain, thereby effectively loosing the tightly stacked polymer chains and reducing a chain interaction.

Further, the fluorene-containing structure is also introduced into the molecular structure of the composite according to the present invention. Since the fluorene-containing polycyclic ring has a refractive index higher than the benzene ring, the introduction of the fluorene group is advantageous for increasing light transmittance of the composite of the present invention. Moreover, the presence of a fluorene unit in the composite can also increase a content of the aromatic unit therein, thereby further improving the thermal stability of the polymer. The current substrate material of an organic light-emitting diode (OLED) still has some disadvantages, and the proposal of the composite material of the present invention provides a new idea to enrich the field of the substrate materials of the OLED.

However, it should be clarified that the polyimide composite according to the present invention is usable as a substrate material for an OLED display panel, and can achieve the above-mentioned advantageous effects, but it is only an application of the polyimide composite according to the present invention, and the polyimide composite according to the present invention is not limited to be used as the substrate material of the OLED display panel, and it can also have a wider applications, for example, as the encapsulating film materials, etc., as long as the performance parameters comply with the application requirements.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A polyimide composite having a molecular structural formula as follow:

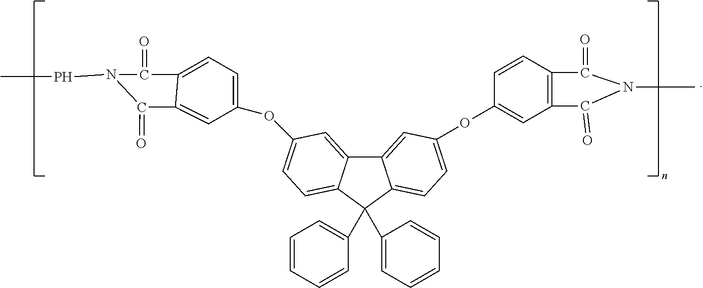

2. The polyimide composite according to claim 1, wherein a polyamic acid precursor of the polyimide composite has a molecular structural formula as follow:

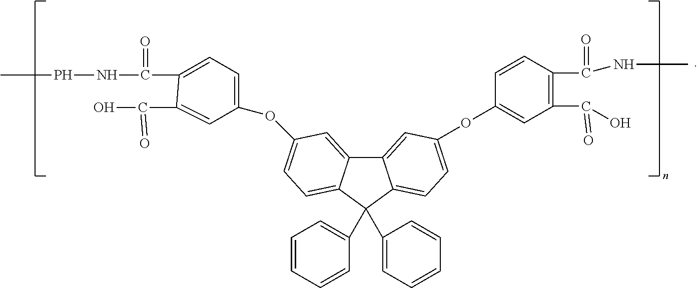

3. The polyimide composite according to claim 2, wherein raw materials for preparing the polyamic acid precursor comprise a diamine (NH₂—PH—NH₂) and a fluorene-containing aromatic dianhydride.

4. The polyimide composite according to claim 3, wherein the fluorene-containing aromatic dianhydride has a molecular structural formula as follow:

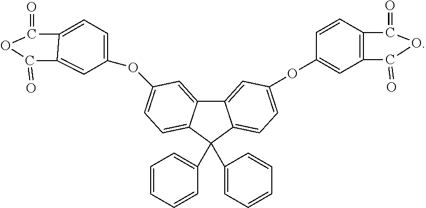 [SMILES: O=C1OC(=O)c2cc(Oc3ccc4c(c3)-c3cc(Oc5ccc6c(c5)C(=O)OC6=O)ccc3C4(c3ccccc3)c3ccccc3)ccc21]

5. The polyimide composite according to claim 3, wherein the PH in the diamine (NH₂—PH—NH₂) has a molecular structural formula selected from one of the following molecular structural formulas a, b and c:

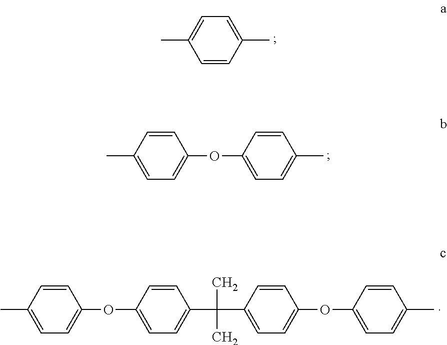

6. The polyimide composite according to claim 4, wherein a raw material for preparing the fluorene-containing aromatic dianhydride comprises a fluorene-containing aromatic dicarboxylic acid, which has a molecular structural formula as follow:

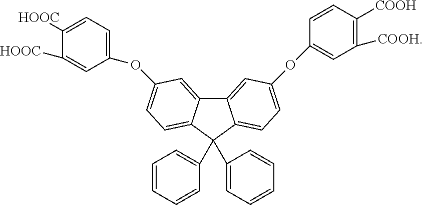 [SMILES: O=C(O)c1ccc(Oc2ccc3c(c2)-c2cc(Oc4ccc(C(=O)O)c(C(=O)O)c4)ccc2C3(c2ccccc2)c2ccccc2)cc1C(=O)O]

7. The polyimide composite according to claim 6, wherein raw materials for preparing the fluorene-containing aromatic dicarboxylic acid comprise fluorene-containing aromatic diol, 4-bromophthalic acid, and toluene.

8. The polyimide composite according to claim 7, wherein the fluorene-containing aromatic diol has a molecular structural formula selected from one of the following molecular structural formulas a, b and c:

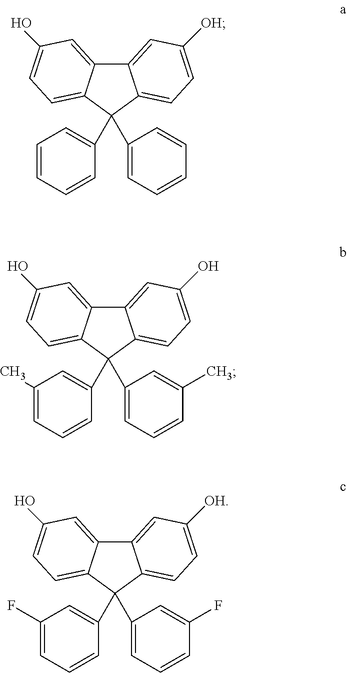 [SMILES: Oc1ccc2c(c1)-c1cc(O)ccc1C2(c1ccccc1)c1ccccc1 ; Cc1cccc(C2(c3cccc(C)c3)c3ccc(O)cc3-c3cc(O)ccc32)c1 ; Oc1ccc2c(c1)-c1cc(O)ccc1C2(c1cccc(F)c1)c1cccc(F)c1]

9. A method of preparing the polyimide composite according to claim 1, comprising the following steps:
Step S1, adding fluorene aromatic diol, 4-bromophthalic acid, toluene, and a solvent to a reaction vessel, stirring at room temperature for 1 to 4 hours, and then heating to 70-90° C. and maintaining the temperature for 10-20 hours, to obtain a mixed solution of fluorene-containing aromatic dicarboxylic acid;
Step S2, adding a mixed solvent of water and ethanol to the mixed solution, stirring the mixed solution at a temperature of 70-90° C. for 48-96 hours for carrying out a reaction, and filtering and washing the mixed solution after the reaction to obtain a fluorene-containing aromatic dianhydride product;
Step S3, adding the fluorene-containing aromatic dianhydride, a diamine, and a solvent to a reaction vessel, and stirring at room temperature for 24 to 96 hours, to obtain a polyamic acid precursor as a reaction product; and
Step S4, adding toluene to the polyamic acid precursor, heating to 150-250° C. for 4-6 hours, then cooling to 70-90° C., filtering the mixed solution after the reaction, removing 60% to 80% of the solvent from the filtered solution, and then carrying out a crosslinking reaction at a constant temperature of 400 to 500° C., thereby obtaining the polyimide composite according to claim 1.

10. A display panel, comprising a substrate layer comprising the polyimide composite according to claim 1.
